(19) United States
(12) Patent Application Publication
(10) Pub. No.: US 2026/0287280 A1
(43) Pub. Date: Sep. 24, 2026

(54) TWO-PHASE FLOW MANIFOLD AND COOLING APPARATUS INCLUDING THE TWO-PHASE FLOW MANIFOLD

(71) Applicant: HRL Laboratories, LLC, Malibu, CA (US)

(72) Inventors: Adam Gross, Santa Monica, CA (US); Christopher Roper, Thousand Oaks, CA (US); David Smith, Newbury Park, CA (US); Jeremy Orosco, Canoga Park, CA (US)

(21) Appl. No.: 19/539,899

(22) Filed: Feb. 13, 2026

Related U.S. Application Data
(60) Provisional application No. 63/775,933, filed on Mar. 21, 2025.

(51) Int. Cl. F28F 3/12; H05K 7/20

(52) U.S. Cl. CPC F28F 3/12; H05K 7/20772; H05K 7/20781

(57) ABSTRACT

A cooling apparatus includes a two‑phase manifold, a finned plate with a microchannel array, and an interface between them. The manifold comprises hierarchical descending passages for liquid inflow and ascending passages for vapor and liquid outflow. Internal surfaces of vapor passages may include a hydrophobic composition and internal surfaces of liquid passages may comprise a hydrophilic composition to passively separate phases. The interface includes gas‑permeable, liquid‑resistant screens or barriers positioned at entrances of ascending vapor passages, and open areas aligned with descending and ascending liquid passages. A vapor outlet may be located at a higher elevation than a liquid outlet. The microchannel array can include divergent microchannels with regions coordinated to the interface. The apparatus may be manufactured monolithically by additive manufacturing or as modular, removably coupled components, and can be operated to maintain a liquid fraction in the microchannel array to reduce dry‑out and flow instabilities.

### CROSS-REFERENCE TO RELATED APPLICATIONS

This application claims priority to and the benefit of U.S. Provisional Patent Application No. 63/775,933, filed on Mar. 21, 2025, the entire content of which is incorporated herein by reference.

### BACKGROUND

### 1. Field

One or more aspects of embodiments of the present disclosure relate to a two-phase thermal management apparatus and cooling systems utilizing the thermal management apparatus. For example, two-phase cooling systems utilizing integrated two-phase manifolding and targeted surface chemistry to passively separate and route vapor and liquid phases. The two-phase thermal management apparatus includes additively manufactured cooling blocks for efficient cooling of high-heat flux devices.

### 2. Description of Related Art

Two-phase cooling systems offer superior performance and efficiency by leveraging the latent heat of vaporization. However, managing the separation and routing of vapor and liquid phases within compact manifolds remains a challenge. For example, improper phase separation can lead to flow instability, reduced heat transfer, and backpressure. Existing two-phase cooling systems often lack dedicated outlet paths for vapor and liquid, resulting in inefficient operation, or rely on geometric separation or external phase separators, which add complexity and size to the manifold.

The present disclosure improves upon these challenges by providing additively manufactured microchannel cooling blocks with two-phase manifolds having passive routing of vapor and liquid streams and beneficial surface chemistry properties, and in some embodiments the routing may be integrated. The benefits of microchannel cooling have been described previously, and manifolded microchannel cooling block designs are known to reduce pressure drop.

The following references are further provided and the entire contents of each of which are incorporated herein by reference:

D. B. Tuckerman and R. F. W. Pease, IEEE Electronic Device Letters, EDL-2, 5, pp. 126-129, 1981.

M. A. Arie, et al., International Journal of Heat and Mass Transfer, 81, pp. 478-489, 2015.

M. P. David et al., International Journal of Heat Mass Transfer, 54 (25-26), pp. 5504-16, 2010.

K. Li et al., Small Structures, 6(4), 2400470, 2025.

T. Kaya and K. Goncharov, Frontiers in Heat Pipes, 2, 013004, 2011.

J. E. Eninger, Priming Foils for Venting Noncondensible Gas from Heat-Pipe Arteries. Chapter in Heat Transfer with Thermal Control Applications, 235-43, 1975.

The present disclosure is related to the following U.S. patent documents issued to HRL: U.S. Patent No. 11,680,756, U.S. Patent Publication No. 2025/0071936, U.S. Patent Application No. 19/332,898, and U.S. Patent Application No. 19/446,619, the entire content of each of which is hereby incorporated by reference.

The preceding information disclosed in this Background section is only for enhancement of understanding of the background and related art of the disclosure and therefore it may contain information that does not constitute prior art. For example, any discussion of publications or patents herein is provided solely for background and is not an admission that any such document constitutes prior art.

### SUMMARY

One or more aspects of embodiments of the present disclosure are directed toward a microchannel cooling block including a two-phase manifold having distinct outlet paths for vapor and liquid. The two-phase manifold includes internal phase separation geometry and directional outlet routing to allow vapor to escape efficiently while directing liquid to a return path. The present disclosure provides architectures that enhance or improve flow stability and thermal performance, and also reduce pressure drop.

The two-phase manifold includes internal surfaces selectively treated to be hydrophobic or hydrophilic to provide continuous or discontinuous wettability gradients that direct vapor and liquid phases along different flow paths. The hydrophilic regions may attract and retain liquid, while the hydrophobic regions may repel liquid and promote vapor flow. In some cases, hydrophilic and hydrophobic bodies and surfaces may be combined to produce discontinuous wettability characteristics that selectively segregate vapor and liquid phases into separate flow paths. The present disclosure provides passive phase separation and routing within the two-phase manifold without the need for mechanical valves or external separators. The microchannel cooling block and two-phase manifold of the present disclosure improve two-phase cooling efficiency, reduce pressure drop, and simplify integration.

The present disclosure provides modular integration for scalable thermal management systems, including those used in AI data centers, aerospace platforms, and/or high-power photonics. The two-phase manifold design ensures uniform coolant distribution, which is desired or suitable or even critical for minimizing thermal gradients and enhancing device reliability.

Additional aspects will be set forth in part in the description which follows and, in part, will be apparent from the description, or may be learned by practice of the presented embodiments of the disclosure.

One or more embodiments of the present disclosure provide a cooling apparatus including a two-phase manifold, a finned plate, and an interface, the two-phase manifold including: a top level including: top descending (TD) passages open to at least one inlet in the top level and configured for a liquid inflow; top ascending vapor (TAV) passages open to at least one vapor outlet in the top level and configured for a vapor discharge; and top ascending liquid (TAL) passages open to at least one liquid outlet configured for a liquid discharge, the at least one liquid outlet being in the top level, a first hierarchical level, or a final hierarchical level, the first hierarchical level including first hierarchical descending (H1D) passages, first hierarchical ascending vapor (H1AV) passages, and first hierarchical ascending liquid (H1AL) passages, the final hierarchical level including final hierarchical descending (HFD) passages, final hierarchical ascending vapor (HFAV) passages, final hierarchical ascending liquid (HFAL) passages, and a bottom boundary, the finned plate including a base plate, a microchannel array, and a top boundary, the microchannel array configured to generate the vapor discharge, the interface configured to separate the vapor discharge and the liquid discharge, the interface including: open areas between the top boundary and the HFD passages and the HFAL passages; and barriers between the top boundary and the HFAV passages, the barriers being gas permeable.

In one or more embodiments, the liquid discharge may be substantially vapor-free or a liquid-vapor mixture.

In one or more embodiments, a size of the TAV passages may be greater than a size of each of the TD passages and the TAL passages, a size of H1AV passages may be greater than a size of each of the H1D passages and the H1AL passages, and a size of the HFAV passages may be greater than a size of each of the HFD passages and the HFAL passages.

In one or more embodiments, the interface may be between the bottom boundary and the top boundary, and the bottom boundary and the top boundary each have a planar outer surface opposite to the interface, or a combination thereof.

In one or more embodiments, the barriers may be substantially liquid impermeable and may include a second hydrophobic composition.

In one or more embodiments, the surfaces of the barriers may include a coating, the coating including the second hydrophobic composition.

In one or more embodiments, the second hydrophobic composition includes a polymeric composition including at least one hydrophobic moiety.

In one or more embodiments, the open areas include a capillary boundary.

In one or more embodiments, each of the H1D passages may be open to the at least one inlet via the TD passages, each of the H1AV passages may be open to the at least one vapor outlet via the TAV passages, each of the H1AL passages may be open to the at least one liquid outlet and the TAL passages, the two-phase manifold further includes a second hierarchical level including second hierarchical descending (H2D) passages open to the H1D passages, second hierarchical ascending vapor (H2AV) passages open to the H1AV passages, and second hierarchical ascending liquid (H2AL) passages open to the H1AL passages, and wherein the H2D passages are greater in number than the H1D passages, the H2AV passages are greater in number than the H1AV passages, and the H2AL passages are greater in number than the H1AL passages.

In one or more embodiments, the at least one liquid outlet may be in the second hierarchical level, the TD passages, the TAV passages, and the TAL passages extend in an initial direction, the H1D passages, the H1AV passages, and the H1AL passages extend in a first direction, the first direction substantially perpendicular to and crossing the initial direction, and the H2D passages, the H2AV passages, and the H2AL passages extend in a second direction, the second direction substantially equivalent to the first direction.

In one or more embodiments, the microchannel array includes fins and microchannels, the fins being connected to and extending from a surface of the base plate, each one of the microchannels being between each adjacent two of the fins, and an interior of the two-phase manifold may be open to (in fluid communication with) the microchannels.

In one or more embodiments, microchannels in the microchannel array extend in a direction parallel to each other and perpendicular to a direction of extension of the HFD passages, and the microchannel array includes linear fins and linear microchannels, or divergent fins and divergent microchannels, the divergent microchannels having large regions under the barriers and small regions under the open areas.

In one or more embodiments, the divergent fins include auxiliary fins in the large regions, and the divergent microchannels are separated microchannels and the divergent fins include partition fins, or the divergent microchannels are connected microchannels.

In one or more embodiments, surfaces of at least a portion of the fins includes at least one coating, the coating including a fluorinated composition, a third hydrophobic composition, a second hydrophilic composition, or combination thereof.

In one or more embodiments, the fins include a thermally conductive material and have a highest thermal conductivity axis with a conductivity of at least about 400 watt per meter degree K (W/m-K), a thickness of the fins may be about 1 micrometer (µm) to about 500 µm, a height of the fins may be about 200 µm to about 5000 µm, the base plate includes aluminum, carbon, copper, gold, molybdenum, nitrogen, palladium, platinum, silicon, silver, tungsten, graphite, diamond, an alloy thereof, a compound thereof, and any suitable combination thereof, a thickness of the base plate may be about 10 µm to about 2000 µm, and a shear modulus of the base plate may be about 10 megapascal (MPa) to about 300 gigapascal (GPa).

In one or more embodiments, the two-phase manifold, the finned plate, and the interface are modular and removably coupled.

One or more embodiments of the present disclosure provide a method of operating the cooling apparatus, the method including: providing the liquid inflow including a coolant to the at least one inlet; flowing the coolant from the at least one inlet to the HFD passages and into the finned plate; vaporizing a first coolant portion to provide the vapor discharge; flowing at least of a portion of the vapor discharge into the HFAV passages; maintaining a liquid fraction within the microchannel array during operation by removing vapor through the HFAV passages to reduce dry-out and flow instabilities; flowing a second coolant portion in the finned plate to provide the liquid discharge; and flowing the liquid discharge into the HFAL passages, wherein an amount of the liquid inflow may be substantially equal to a total of an amount of the first coolant portion and an amount of the second coolant portion.

One or more embodiments of the present disclosure provide a method of making the cooling apparatus, the method including: forming the two-phase manifold having the top, first hierarchical, and final hierarchical levels with descending passages, ascending vapor passages, and ascending liquid passages; forming the finned plate having the microchannel array; arranging the interface and the barriers between the top boundary of the finned plate and entrances of the HFAV passages; and coupling the two-phase manifold to the finned plate across the interface.

One or more embodiments of the present disclosure provide a cooling system including: at least one cooling apparatus of the present disclosure; at least one pump configured to circulate a coolant; at least one heat exchanger in fluid communication with the two-phase manifold of the cooling apparatus; an electronic component, the cooling apparatus on the electronic component; and a heat exchanger in fluid communication with the two-phase manifold of the cooling apparatus.

One or more embodiments of the present disclosure provide a data center including: a plurality of electronic components; and at least one cooling system of the present disclosure, wherein the plurality of cooling apparatuses are on the plurality of electronic components.

In certain embodiments, a cooling apparatus includes a two‑phase manifold with hierarchical descending passages for liquid inflow and ascending passages for vapor and liquid outflow, a finned plate having a microchannel array where boiling occurs, and an interface configured to separate vapor from liquid utilizing gas‑permeable barriers and/or hydrophobic screens. Internal surfaces of vapor passages may include a hydrophobic composition, while internal surfaces of liquid passages may include a hydrophilic composition to passively route phases toward dedicated outlets positioned at different elevations.

### BRIEF DESCRIPTION OF THE DRAWINGS

The features and advantages of embodiments of the present disclosure will be better understood by reference to the following detailed description if (e.g., when) considered in conjunction with the accompanying drawings.

FIG. 1 is a schematic perspective view of a cooling apparatus according to one or more embodiments of the present disclosure.

FIG. 2A is a schematic perspective view of a microchannel array and final hierarchical level according to one or more embodiments of the present disclosure.

FIG. 2B is an expanded view of area 2B of FIG. 2A.

FIG. 3 is a perspective view of a final hierarchical level of a two-phase manifold, an interface, and a microchannel array according to one or more embodiments of the present disclosure.

FIG. 4 is an expanded view of FIG. 2B.

FIG. 5A and 5B are schematic plan views of divergent microchannel arrays according to one or more embodiments of the present disclosure.

### DETAILED DESCRIPTION

The following description sets forth one or more suitable example embodiments and details in order to provide a more thorough understanding of the present disclosure. However, the subject matter of the present disclosure may be embodied in many different forms, and is not limited to the embodiments and details set forth herein. All disclosed features may be replaced with comparable features serving the same, equivalent, or similar purpose, unless expressly stated otherwise. Features of one embodiment may be incorporated into other embodiments unless expressly stated otherwise.

In the drawings, the same or similar reference numerals refer to the same or similar elements throughout, and duplicative descriptions thereof may not be provided. The drawings are not necessarily drawn to scale, and thicknesses and dimensions of elements may be exaggerated for clarity.

Unless otherwise defined, all chemical names, technical and scientific terms, and terms defined in common dictionaries should be interpreted as having meanings consistent with the context of the related art and should not be interpreted in an ideal or overly formal sense.

As utilized herein, expressions such as "at least one of," "one of," "at least one selected from among,” and "selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, and/or one or more (e.g., any suitable) combinations thereof disclosed in the specification and are not intended to preclude the possibility that one or more other features, numbers, steps, actions, components, parts, ingredients, materials, and/or one or more (e.g., any suitable) combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize/utilization,” “utilizing,” and “utilized,” respectively.

In this context, “consisting essentially of” refers to that any additional components will not materially affect the chemical, physical, optical or electrical properties of the semiconductor film.

Furthermore, any claim element that does not explicitly recite a “means for” or “step for” in performing a function, is not to be interpreted as a “means” or “step” clause under 35 U.S.C. § 112(f). The use of “step of” or “act of” in the claims herein is not intended to invoke the provisions of 35 U.S.C. § 112(f).

It will be understood that if (e.g., when) an element (e.g., layer) is referred to as being “outside,” “inside,” “on,” “above,” “below,” “connected to,” or “coupled to” another element, it may be in direct contact with the other element, or one or more intervening elements may be present. In contrast, if (e.g., when) an element (e.g., layer) is referred to as being “directly” on, above, below, and/or the like. another element, no intervening elements are present. Terms describing spatial relationships between elements or features (such as “below,” “lower,” “under,” “above,” “upper,” and/or the like.) should be interpreted in the context of the device as a whole. For example, an element described as being “under” a second element could be alternatively described as being “above” the second element in an alternative orientation, if (e.g., when) such orientation is available.

Example embodiments of the present disclosure will be described with reference to the accompanying drawings. In the drawings, the same or similar reference numerals refer to the same or similar elements throughout, and duplicative descriptions thereof may not be provided the specification. The thickness of layers, films, panels, regions, and/or the like, are exaggerated for clarity. It will be understood that if (e.g., when) an element such as a layer, film, region, or substrate is referred to as being “on” another element, it can be directly on the other element or intervening element(s) may also be present. In contrast, if (e.g., when) an element is referred to as being “directly on” another element, there are no intervening elements present.

Herein, the use of the term “may,” if (e.g., when) describing embodiments of the present disclosure, refers to “one or more embodiments of the present disclosure.” In addition, the use of alternative language, such as “or,” if (e.g., when) describing embodiments of the present disclosure, refers to “one or more embodiments of the present disclosure” for each corresponding item listed. For example, “A or B” is construed to include A, B, A+B, and/or the like. Similarly, the term "and/or" includes any and all combinations of one or more of the associated listed items. The symbol “/” as utilized herein, may be interpreted as “and” or “or” according to the context. Also, the term “exemplary”, “preferred”, “preferable”, “preferably”, and/or the like is intended to refer to an example, embodiment, or illustration.

All references herein to the/our “disclosure”, “invented idea”, “our system”, “this system” (in context with “our system”), “proposed system”, “innovative method”, “inventive concept”, “method”, “this circuit”, “this architecture”, “this”, “the present disclosure”, and/or the like shall refer to one or more embodiments of present disclosure.

### Introduction

The present disclosure provides a two-phase manifold having multiscale hierarchically interlaced flow routing, that leverages the heat exchangers and manifolds in U.S. Patent No. 11,680,756 and U.S. Patent Publication No. 2025/0071936, and the vapor venting strategies in U.S. Patent Application No. 19/446,619, with important innovations for passively separating and managing vapor and liquid flows using geometric strategies, functionalized internal surface coatings, and/or usage of materials with differing tailored wetting characteristics. For example, the designs of the present disclosure include a microchannel array where vaporization occurs, membranes that selectively permit vapor passage while maintaining a capillary interface, a vapor outlet at the top of the manifold to allow buoyant vapor to escape, a liquid outlet at a lower elevation to collect condensed or residual liquid, flow passages having converging/diverging inlet/outlet structure having a diamond pattern or a zig zag pattern, optimal or suitable short-throw recirculation paths, configurations for reducing undesirable bypass flow within the gap between the fins and the manifold (elastomeric extrusions from fins, flat interfacing with o-ring groove depth optimization), and all-in-one (manifold + cooling block) design and production using additive manufacturing (LPBF, electrochemical additive manufacturing (ECAM), SLA, etc.) methods.

The flow passages and microchannels of the present disclosure include the following features. Hydrophilic treated regions on internal surfaces to attract and retain liquid coolant, which may be created using surface coatings, chemical treatments, or micro- and/or nano-structuring. Hydrophobic treated regions on internal surfaces to repel liquid coolant and promote vapor flow, which may guide vapor toward dedicated outlet ports or vapor collection zones. Phase-selective routing by manifold geometry and surface patterning that direct liquid and vapor along separate paths. For example, vapor may be routed upward through hydrophobic channels, while liquid is retained in lower hydrophilic channels. Vapor extraction screens such as porous or mesh structures treated with hydrophobic coatings to allow vapor to pass while blocking liquid. Vapor venting interfaces with prescribed geometries or wetting characteristics that maintain capillary pressure at the scale of the venting pores while permitting or promoting the passage of vapor while retaining liquid. As used herein and unless stated otherwise, “hydrophilic” surfaces may exhibit an equilibrium water contact angle less than about 90°, and “hydrophobic” surfaces may exhibit an equilibrium water contact angle greater than about 90°, measured on flat coupons of the same material/coating.

The interfaces may interact with non-aqueous fluids in a manner different than “hydrophobic” and “hydrophilic.” However, a surface may generally be characterized as fluidphilic if (e.g., when) it exhibits a contact angle with a non-aqueous fluid of less than about 90°, and fluidphobic when the contact angle is greater than about 90°. Regarding non-aqueous fluids, the terms “fluidphilic” and “fluidphobic,” as used herein, are interchangeable with “hydrophilic” and “hydrophobic,” respectively.

In terms of efficiency, an optimal or suitable or desired design provides minimal or reduced amount of required power input. Both pressure drop and flow rate are directly associated with this input power, and thus minimizing or reducing pressure drop and/or flowrate while maintaining performance is desirable.

In terms of performance, a reduced specific thermal resistance (i.e., inverse total heat transfer coefficient) enables the removal of large heat loads (typically in this case, multiple kilowatts) without a large rise in temperature across the heat transfer interface, and over relatively small areas (typically in this case, one kilowatt dissipated over less than three square centimeters). The thermal resistance of a two-phase fluid cooling block may include thermal resistance of solid conduction, thermal resistance of convection, thermal resistance of sensible heat gain, vapor-liquid interfacial phase change thermal resistance, vapor phase thermal resistance, and/or thermal resistance of a thermal interface material between the heat source and the cooling block.

The present disclosure outperforms existing methods by providing highly efficient motivation of fluid through the cooling block, enabled by reduced or minimized recirculating paths through channels to reduce frictional pressure drop, multi-stage turbulence mitigation to reduce turbulent pressure drop, Poiseuille flow partitioning to improve flow/pressure distribution uniformity, reducing pressure drop extrema, and symmetric hierarchical manifolding (inlet/outlet configuration) to improve flow/pressure distribution uniformity, reducing pressure drop extrema. The present disclosure provides a passive method of utilizing wetted capillary vapor-venting interfaces to impose a pressure differential around the interface when venting intra-channel vapor into a separate vapor channel without substantially increasing the intra-channel pressure drop and without the need for energy input to an active method of maintaining the pressure differential (e.g., vacuum).

The present disclosure may be utilized in suitable applications where thermal management of high heat load (multiple kilowatts) and/or high heat flux (hundreds of watts per square centimeter) producing devices is required under significant size, weight, and/or efficiency constraints. Commercial applications include but are not necessarily limited to: power electronics (power transistors, amplifiers, etc.), densely populated integrated circuits (ICs) used for computational tasks (CPUs and GPUs, in particular those used in AI datacenters), communications systems (radar, microwave, 5G, etc.), and high power laser applications (LIDAR), directed energy microwave systems, particle accelerator components (especially targets), aerothermal heating in high speed flight, fusion reactor walls and blankets, and radio detection and ranging (RADAR) systems.

The present disclosure is the combined result of rigorous physics-based design decisions and a long, substantial iterative “try and fail” development process. Although some work has been done previously investigating some aspects of efficient microchannel cooling blocks, most of these studies have considered theoretical extrapolations of the principles and thus were limited by a lack of iterative development. The preceding innovations, most of which are synergistic in their contribution to efficiency and/or performance, were not immediately obvious due to the need to combine theoretical investigations with the ground truth provided by lab testing and development. Many were arrived at only after the latter was addressed. The resulting validated performance of the invention demonstrates marketability toward thermal management of next-generation heat flux producing electronics beyond what was previously thought possible by microchannel cooling blocks.

According to one or more embodiments of the present disclosure, a cooling apparatus includes a two-phase manifold, a finned plate, and an interface between the two-phase manifold and the finned plate. The cooling apparatus may be a cooling block, e.g., a microchannel cooling block, as described in more detail herein.

### Two-Phase Manifold

A top level of the two-phase manifold includes at least one inlet configured for a cool liquid inflow, at least one liquid outlet configured for a warm liquid discharge, and at least one vapor outlet configured for a vapor discharge (e.g., warm vapor discharge), but the present disclosure is not limited thereto. For example, the top level may have one inlet for cool liquid inflow, one liquid outlet for warm liquid discharge, and one vapor outlet; or may have one or more inlets for cool liquid inflow, one or more liquid outlets for warm liquid discharge, and one or more vapor outlets; or may have two or more inlets for cool liquid inflow, two or more liquid outlets for warm liquid discharge, and two or more one vapor outlets, and suitable combinations thereof. In some embodiments, the top level of the two-phase manifold may exclude (e.g., not have) a liquid outlet as described in more detail herein.

The cool liquid inflow may be a coolant stream, such as a single-phase coolant, a two-phase coolant, or a combination thereof. The coolant stream may be a liquid coolant, but the present disclosure is not limited thereto. The coolant stream may include water, ethylene glycol, propylene glycol, oils, air, refrigerants, hydrocarbons, halocarbons (e.g., hydrohalocarbons, hydrofluorocarbons, chlorofluorocarbons, hydrofluoroolefins, hydrohaloolefins,) natural refrigerants (e.g. ammonia, carbon dioxide, propane, isobutane, and/or the like) and/or one or more (e.g., any suitable) combinations thereof. The warm liquid discharge includes thermal energy absorbed by the coolant stream (e.g., from a component coupled to the cooling apparatus) and may be substantially vapor-free or may be a liquid-vapor mixture. The vapor discharge is produced as the coolant stream absorbs thermal energy and undergoes a phase change, to enhance or increase the efficiency of the cooling apparatus of the present disclosure. The vapor discharge may be substantially liquid-free or may be a liquid-vapor mixture. For example, the vapor discharge may be neat, e.g., greater than 99.9% liquid-free. References to “cool” and “warm” herein are for ease of explanation but are non-limiting, and these terms may be replaced by “first” and “second” without affecting the disclosure.

The top level has top descending (TD) passages open to the inlet through which the cool coolant stream flows downward and/or inward, top ascending vapor (TAV) passages open to the vapor outlet through which the vapor discharge flows upward and/or outward, and top ascending liquid (TAL) passages open to the liquid outlet through which the warm liquid discharge flows upward and/or outward. A size of the TAV passages may be greater than a size of the TD passages and/or the TAL passages to accommodate the larger volume of the vapor discharge produced as the liquid coolant stream changes phase. The larger size of the ascending vapor passages (e.g., TAV passages) maintains a lower pressure for the vapor as it flows through the two-phase manifold and facilitates separation and/or removal of the liquid discharge from the vapor discharge. For example, the TAV passages may have a diameter, cross-sectional area, hydraulic area, hydraulic volume, and/or the like that is greater than that of the TD passages and/or the TAL passages. The TD passages may have a diameter, cross-sectional area, hydraulic area, hydraulic volume, and/or the like that is about equal to that of the TAL passages. In some embodiments, the TAV passages may be less than or equal to that of the TD passages and/or the TAL passages.

The cool coolant stream is described as flowing downward through the TD passages and the warm liquid discharge is described as flowing upward through the TAL passages, but the present disclosure is not limited thereto. It will be appreciated that the two-phase manifold may have a reverse configuration wherein the cool liquid coolant stream is described as flowing downward through the TAL passages and the warm liquid discharge is described as flowing upward through the TD passages.

The two-phase manifold includes a first hierarchical level below the top level and a final hierarchical level below the first hierarchical level. References to “below” and “above” herein are for ease of explanation but are non-limiting, and these terms may be replaced by “first” and “second” without affecting the disclosure. The hierarchical levels of the two-phase manifold have “hierarchically interlaced multiscale flow manifolding (HIMFM)” that denotes an arrangement of two or more manifolding levels (e.g., first/second/final) that are interlaced across different layers and scales such that discrete streams are progressively subdivided and/or laterally redistributed to deliver substantially uniform face velocity to corresponding passages while maintaining counterflow. “First” and “final” refer to positions along a manifolded flow path from an inlet (first) toward the center and from the center toward the outlet (final) and do not imply order of manufacture. “Second,” “third,” and/or the like, when present, denote intermediate manifolding levels that feed or collect from finer or coarser levels. The phrases “open to” and “in fluid communication with” are equivalent phrases that refer to passages and/or the like through which a fluid can flow, directly or via intermediate manifolding. For example, fluid in the first hierarchical level communicates with fluid in the final hierarchical level and any intermediate hierarchical level(s).

In one or more embodiments, the number of passages in an “n+1” hierarchical level may be greater, less or the same as the number of passages in the “n” hierarchical level. It will be appreciated that a greater number of passages in an “n+1” hierarchical level compared to an “n” hierarchical level refers to the construction and geometry of the hierarchical level and/or passages. In other words, the number of passages in a hierarchical level is not determined or selected by separators and/or dividers to the passages, where the separators and/or dividers may be introduced into the design (e.g., in CAD software) after the primary hierarchical passages are established in order to further discretize the flow to obtain beneficial flow properties such as reducing the hydraulic diameter and Reynolds number in order to suppress turbulence and mitigate pressure drop.

The size of passages in an “n+1” hierarchical level may be less than the size of passages in an “n” hierarchical level. In one or more embodiments, the size of passages in an “n+1” hierarchical level may be the same as the size of passages in an “n” hierarchical level. In one or more embodiments, the size of passages in an “n+1” hierarchical level may be greater than the size in an “n” hierarchical level.

The two-phase manifold may have equal numbers of hierarchical levels with ascending passages and descending passages. In one or more embodiments, the number of hierarchical levels having ascending passages may be greater or less than the number of hierarchical levels having descending passages.

The first hierarchical level includes first hierarchical descending (H1D) passages open to the inlet via the TD passages, first hierarchical ascending vapor (H1AV) passages open to the vapor outlet via the TAV passages, and first hierarchical ascending liquid (H1AL) passages open to the liquid outlet and the TAL passages.

The H1D passages may be greater or less in number than the TD passages, the H1AV passages may be greater or less in number than the TAV passages, and the H1AL passages may be greater or less in number than the TAL passages. In some embodiments, the number of H1D passages may be the same as the number of TD passages, the number of H1AV passages may be the same as the number of TAV passages, and the number of H1AL passages may be the same as the number of TAL passages.

A size of H1D passages may be greater than that of the TD passages, a size of the H1AV passages may be greater than that of the TAV passages, and a size of the H1AL passages may be greater than that of the TAL passages. A size of H1AV passages may be greater than a size of the H1D passages and/or a size of the H1AL passages. For example, the H1AV passages may have a diameter, cross-sectional area, hydraulic area, hydraulic volume, and/or the like that is greater than that of the H1D passages and/or the H1AL passages. The H1D passages may have a diameter, cross-sectional area, hydraulic area, hydraulic volume, and/or the like that is about equal to that of the H1AL passages. In some embodiments, the size of H1AV may be less than or equal to the size of the H1D passages and/or the size of the H1AL passages.

In certain embodiments of the present disclosure, the at least one liquid outlet may be in the first hierarchical level instead of the top level. In these embodiments, the top level of the two-phase manifold has no TAL passages liquid and does not discharge

a liquid stream but does include the cool liquid inflow. For example, the warm liquid discharge may pass through the at least one liquid outlet in the first hierarchical level. In some embodiments, the at least one liquid outlet is not in the top level and may instead be in a second, third, or other hierarchical level and/or the first hierarchical level.

In one or more embodiments, the final hierarchical level includes descending passages that discharge liquid directly into a microchannel array of the finned plate, ascending vapor passages that receive vapor generated within the microchannel array, and ascending liquid passages that receive warm liquid discharge from the microchannel array. For example, the final hierarchical level includes final hierarchical descending (HFD) passages open to the H1D passages, final hierarchical ascending vapor (HFAV) passages open to the H1AV passages, and final hierarchical ascending liquid (HFAL) passages open to the H1AL passages.

The HFD passages may be greater or less in number than the H1D passages, the HFAV passages may be greater or less in number than the H1AV passages, and the HFAL passages may be greater or less in number than the H1AL passages. In some embodiments, the number of HFD passages may be the same as the number of H1D passages, the number of HFAV passages may be the same as the number of H1AV passages, and the number of HFAL passages may be the same as the number of H1AL passages.

A size of HFD passages may be greater than that of the H1D passages, a size of the HFAV passages may be greater than that of the H1AV passages, and a size of the HFAL passages may be greater than that of the H1AL passages. A size of the HFAV passages may be greater than a size of the HFD passages and/or a size of the HFAL passages. For example, the HFAV passages may have a diameter, cross-sectional area, hydraulic area, hydraulic volume, and/or the like that is greater than that of the HFD passages and/or the HFAL passages. The HFD passages may have a diameter, cross-sectional area, hydraulic area, hydraulic volume, and/or the like that is about equal to that of the HFAL passages. In some embodiments, the size of HFD passages may be less than or equal to that of the H1D passages, the size of the HFAV passages may be less than or equal to that of the H1AV passages, and the size of the HFAL passages may be less than or equal to that of the H1AL passages. The size of the HFAV passages may be less than or equal to that of the HFD passages and/or the size of the HFAL passages. For example, the HFAV passages may have a diameter, cross-sectional area, hydraulic area, hydraulic volume, and/or the like that is less than or equal to that of the HFD passages and/or the HFAL passages. The HFD passages may have a diameter, cross-sectional area, hydraulic area, hydraulic volume, and/or the like that is less than or equal to that of the HFAL passages.

The two-phase manifold may include added hierarchical levels, such as a second, third, or a further hierarchical level. In one or more embodiments, the two-phase manifold may include a second hierarchical level, e.g., between the first hierarchical level and the final hierarchical level. The second hierarchical level may include second hierarchical descending (H2D) passages open to the H1D and HFD passages, second hierarchical ascending vapor (H2AV) passages open to the H1AV and HFAV passages, and/or second hierarchical ascending liquid (H2AL) passages open to the H1AL and HFAL passages.

The H2D passages may be greater or less in number than the H1D passages and greater or less in number than the HFD passages, the H2AV passages may be greater or less in number than the H1AV passages and greater or less in number than the HFAV passages, and the H2AL passages may be greater or less in number than the H1AL passages and greater or less in number than the HFAL passages. In some embodiments, the number of H2D passages may be the same as the number of H1D passages and/or the number of HFD passages, the number of H2AV passages may be the same as the number of H1AV passages and/or the number of HFAV passages, and the number of H2AL passages may be the same as the number of H1AL passages and/or the number of HFAL passages.

A size of H2D passages may be greater than that of the H1D passages and less than that of the HFD passages, a size of the H2AV passages may be greater than that of the H1AV passages and less than that of the HFAV passages, and a size of the H2AL passages may be greater than that of the H1AL passages and less than that of the HFAL passages. A size of the H2AV passages may be greater than a size of the H2D passages and/or a size of the H2AL passages. For example, the H2AV passages may have a diameter, cross-sectional area, hydraulic area, hydraulic volume, and/or the like that is greater than that of the H2D passages and/or the H2AL passages. The H2D passages may have a diameter, cross-sectional area, hydraulic area, hydraulic volume, and/or the like that is about equal to that of the H2AL passages. In some embodiments, the size of H2D passages may be less than that of the H1D passages and greater than that of the HFD passages, the size of the H2AV passages may be less than that of the H1AV passages and greater than that of the HFAV passages, and the size of the H2AL passages may be less than that of the H1AL passages and greater than that of the HFAL passages. The size of the H2AV passages may be less than that of the H2D passages and/or the size of the H2AL passages. For example, the H2AV passages may have a diameter, cross-sectional area, hydraulic area, hydraulic volume, and/or the like that is less than that of the H2D passages and/or the H2AL passages. The H2D passages may have a diameter, cross-sectional area, hydraulic area, hydraulic volume, and/or the like that is less than or greater than that of the H2AL passages. In some embodiments, the size of H2D passages may equal that of the H1D passages and/or that of the HFD passages, the size of H2AV passages may equal that of the H1AV passages and/or that of the HFAV passages, the size of H2AL passages may equal that of the H1AL passages and/or that of the HFAL passages, or combinations thereof.

In one or more embodiments, within a common hierarchical level, each ascending vapor passage has a larger average hydraulic diameter than each of a corresponding descending passage and a corresponding liquid-return ascending passage. As used herein, the phrase “average hydraulic diameter” is 4 × a flow area/wetted perimeter averaged along a passage length, unless stated otherwise. In one or more embodiments, within a common hierarchical level, each ascending vapor passages has a smaller average hydraulic diameter than each of a corresponding descending passage and a corresponding liquid-return ascending passage.

The surface energy of internal surfaces of the vapor passages may be configured to repel the liquid phase coolant stream and the surface energy of internal surfaces of the liquid passages may be configured to attract the liquid phase coolant stream. The surface energy may be selected by the material of construction of the passages and/or by including a coating, e.g., composition, on the surfaces.

In one or more embodiments, internal surfaces of each of the TD passages, the H1D passages, the H2D passages, the HFD passages, the TAL passages, the H1AL passages, the H2AL passages, and/or the HFAL passages may include a first hydrophilic composition. The term “hydrophilic” as used herein refers to pro-wetting characteristics such as a high affinity for the composition of the coolant stream. In embodiments that include non-aqueous coolant streams the term “hydrophilic” may refer to “liquidphilic” pro-wetting characteristics such as a high affinity for the composition of the non-aqueous coolant stream. If (e.g., when) the coolant stream is aqueous-based then the hydrophilic composition has an affinity or attraction to aqueous liquids. If (e.g., when) the coolant stream is non-aqueous-based then the hydrophilic composition has an affinity or attraction to non-aqueous liquids, e.g., hydrocarbons and organic solvents. The first hydrophilic composition facilitates adhesion of the coolant stream and liquid discharge to the liquid passages and prevents or reduces adhesion of the vapor discharge to the liquid passages. The first hydrophilic composition may include at least one hydrophilic moiety, or may be a polymeric composition including at least one hydrophilic moiety. The first hydrophilic composition may include silanes and/or may be applied by physical vapor deposition, chemical vapor deposition, plasma treatment, and/or the like. For example, the first hydrophilic composition may include metals, glasses, ceramics (including those formed when metal surfaces oxidize), polymers, surface coatings, surface texture treatments, and/or the like. In some embodiments, the first hydrophilic composition may include ceramics formed by oxidation of metal, e.g., on the surface of the passages.

In one or more embodiments, internal surfaces of each of the TAV passages, the H1AV passages, the H2AV passages, and/or the HFAV passages may include a first hydrophobic composition having non-wetting and/or liquid resistant properties. The term “hydrophobic” as used herein may refer to resistance to an aqueous (water-based) coolant stream. In embodiments that include a non-aqueous coolant stream the term “hydrophobic” may refer to “liquidphobic” resistance to a composition of the non-aqueous coolant stream. If (e.g., when) the coolant stream is aqueous-based then the hydrophobic composition has resistance to or repels aqueous liquids. If (e.g., when) the coolant stream is non-aqueous-based then the hydrophobic composition has resistance to or repels non-aqueous liquids, e.g., hydrocarbons and organic solvents. The first hydrophobic composition prevents or reduces adhesion of the coolant stream and liquid discharge to the vapor passages and facilitates adhesion of the vapor discharge to the vapor passages.

The first hydrophilic composition and the first hydrophobic composition facilitate separation of the vapor discharge from the coolant stream and the liquid discharge, direct the vapor discharge toward the vapor ascending passages and direct the liquid discharge toward the liquid ascending passages. The first hydrophilic composition and the first hydrophobic composition facilitate routing of the vapor discharge toward the vapor outlet and the liquid discharge toward the liquid outlet.

The first hydrophobic composition may include at least one hydrophobic moiety, or may be a polymeric composition including at least one hydrophobic moiety. The hydrophobic moiety may include halogens (e.g., fluorides), fluorocarbons, perfluorinated groups, alkyl hydrocarbons, aryl hydrocarbons, heteroaryl hydrocarbons, polyphenylene oxides, polystyrenes, and/or the like, but the present disclosure is not limited thereto. The polymeric composition may include halogens (e.g., fluorides), fluorocarbons, perfluorinated groups, alkyl hydrocarbons, aryl hydrocarbons, heteroaryl hydrocarbons, polyphenylene oxides, polystyrenes, fluorinated silanes, PTFE, FEP, perfluoropolyethers, Teflon™, and/or the like, but the present disclosure is not limited thereto.

In one or more embodiments, the first hydrophilic composition is present on internal surfaces along a flow path from the inlet to the microchannel array and on liquid-return ascending passages, and the first hydrophobic composition is absent from those internal surfaces.

In one or more embodiments, the first hydrophilic composition is present only on, or near, the liquid outflow and inflow interfaces to retain a liquid layer and prevent vapor from getting into the liquid passages.

In one or more embodiments, the first hydrophobic composition is present on internal surfaces along a flow path from the microchannel array to the vapor outlet and is absent from internal surfaces of the descending passages and the ascending liquid passages.

In one or more embodiments, the first hydrophobic composition is present only on, or near, the vapor venting interfaces to prevent liquid from getting into the vapor ascending passages.

The TD passages, the TAV passages, and the TAL passages may extend in an initial direction and the H1D passages, the H1AV passages, and the H1AL passages extend in a first direction. For example, the first direction may be substantially perpendicular to the initial direction, and may cross the initial direction. The HFD passages, the HFAV passages, and the HFAL passages may extend in a final direction, which may be substantially equal to the initial direction, and may be substantially perpendicular to the first direction, and may cross the first direction. The H2D passages, the H2AV passages, and the H2AL passages may extend in a second direction, which may be substantially perpendicular to the final direction, and may cross the final direction. In some embodiments, the “n+1” hierarchical level may contain passages that extend in a direction that is substantially perpendicular to the passages in the “n” hierarchical level. In some embodiments, the “n+1” hierarchical level may contain passages that extend in a direction that may cross the direction of the passages in the “n” hierarchical level.

In one or more embodiments, the vapor outlet may be at an elevation of the two-phase manifold that is higher than (e.g., above) the liquid outlet. It will be appreciated, that locating the vapor outlet higher than (e.g., above) the liquid outlet may facilitate separation and removal of the vapor discharge the liquid discharge and coolant stream and enhance or increase the efficiency of the cooling apparatus.

In one or more embodiments, the liquid outlet may be in the first hierarchical level, the second hierarchical level, or the final hierarchical level.

In one or more embodiments, at least one auxiliary liquid outlet may be located in the first, second, final, or a further hierarchical level. The auxiliary liquid outlet(s) may be in addition to the liquid outlet in the top level as described herein. In one or more embodiments, the auxiliary liquid outlet(s) may be primary (e.g., only) liquid outlet(s), such that the liquid outlet in the top level is effectively not included in (e.g., excluded from) the two-phase manifold. It will be appreciated, that locating primary liquid outlet(s) below the vapor outlet may facilitate separation and removal of the liquid discharge from the vapor discharge and enhance or increase the efficiency of the cooling apparatus, e.g., in cases where gravity (and thus buoyancy) is dominant over surface tension, as determined by passages that are significantly larger than the capillary length scale associated with the coolant (for example, the capillary length scale of water at standard temperature and pressure is roughly 2.7 mm). For passages that are much smaller than this length scale (for example, water in microchannels with 1 mm tall fins), surface tension forces may dominate over gravitational forces and it may be possible to impart other strategies, such as vapor passages that are below the water passages, with respect to gravity.

The inlet and the outlets of the two-phase manifold may include a thermal isolation layer having gas-filled cavity, an aerogel, or a low-conductivity polymer.

The two-phase manifold may include at least one flow control element including at least one valve, at least one variable orifice, and/or at least one deformable membrane configured to dynamically adjust flow distribution.

As used herein and unless stated otherwise, within any common hierarchical level, ascending vapor passages may be sized with a larger average hydraulic diameter than corresponding descending and ascending liquid passages to accommodate vapor expansion while reducing pressure drop.

### Example Manifold

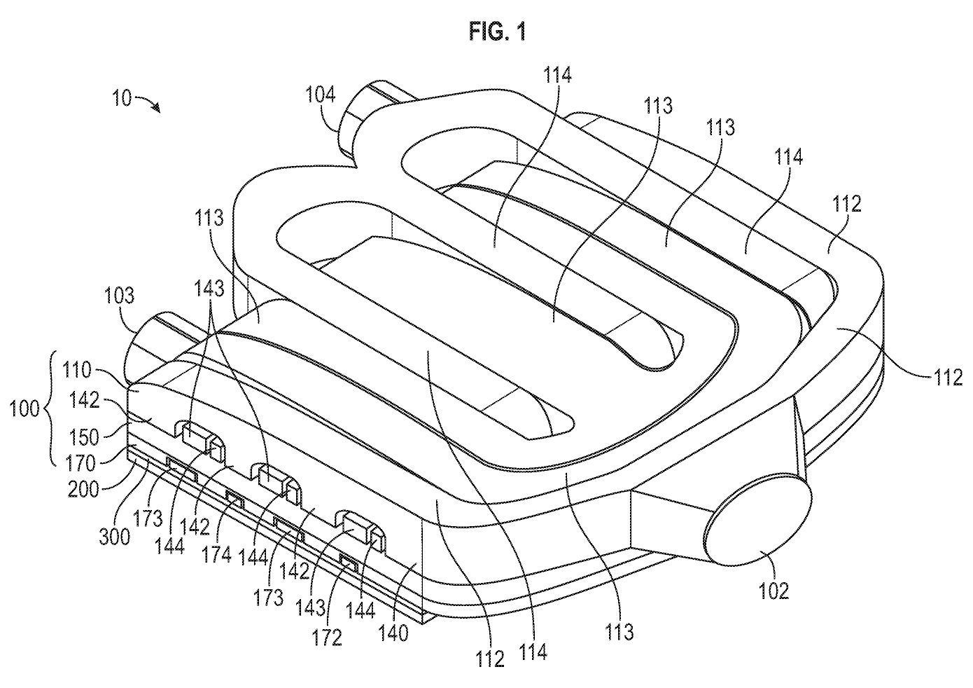

FIG. 1 shows an example cooling apparatus 10 having a two-phase manifold 100, a finned plate 200, and an interface 300 between the two-phase manifold 100 and the finned plate 200, as described in more detail herein. A top level 110 of the two-phase manifold 100 includes an inlet 102 for the coolant stream (e.g., cool liquid coolant), a vapor outlet 103 for the vapor discharge, and a liquid outlet 104 for the warm liquid discharge. Here, reference to “warm” and “cool” is only for ease of explanation, and terms can be replaced by “first” and “second” without affecting the disclosure. In one or more embodiments, the two-phase manifold 100 includes a plurality of (at least one) inlets 102, a plurality of (at least one) vapor outlets 103, and a plurality of (at least one) liquid outlets 104.

The inlet 102, vapor outlet 103, and liquid outlet 104 protruding (e.g., extending) from the top level 110 in a direction parallel to the direction fluid(s) flow through top level 110, but the present disclosure is not limited thereto. For example, the inlet and outlets may protrude (e.g., extend) in a direction perpendicular to the direction fluid(s) flow through top level 110. Other suitable arrangements of the inlet and outlets are contemplated, such an inlet(s) and outlets extending at a 45º angle with respect to the direction fluid(s) flow through top level 110, or inlet(s) and outlets protruding (e.g., extending) above and/or below the two-phase manifold 100. In other embodiments, the inlet(s) and outlets may extend in different suitable directions from each other and may be suitably varied to meet space requirements in a desired application (e.g., may be suitably designed to fit into a predetermined space). The inlet(s) and outlets may independently include a flange, threaded opening, barbed connection, welded joint, etc. for fluid connection to a fluid handling system (e.g., an air conditioning system, a turbocharging system, radiator, heat exchanger, pumped fluid loop, and/or the like).

The top level 110 includes top ascending vapor (TAV) passages 113 having a greater hydraulic volume than that of top descending (TD) passages 112 and top ascending liquid (TAL) passages 114, but the present disclosure is not limited thereto. A first hierarchical level 140 includes first hierarchical ascending vapor (H1AV) passages 143 having a greater hydraulic volume than that of first hierarchical descending (H1D) passages 142 and first hierarchical ascending liquid (H1AL) passages 144. A second hierarchical level 150 includes second hierarchical ascending vapor (H2AV) passages, second hierarchical ascending liquid (H2AL) passages, and second descending (H2D) passages. A final hierarchical level 170 includes final hierarchical ascending vapor (HFAV) passages 173 having a greater hydraulic volume than that of final hierarchical descending (HFD) passages 172 and final hierarchical ascending liquid (HFAL) passages 174.

Each hierarchical level below another has smaller and more passages to progressively partition streams as they flow from top level 110 to first level 140 to final level 170. Each hierarchical level above another has larger and fewer passages to progressively coalesce streams as they flow from final level 170 to first level 140 to top level 110, but the present disclosure is not limited thereto. In some embodiments, for example, the coolant stream may be partitioned from top level 110 to final hierarchical level 170 directly and/or the vapor discharge may be coalesced from final hierarchical level 170 to top level 110 directly. A fluid impermeable barrier (e.g., solid material), between adjacent warm and cool fluid passages prevents mixing of warm and cool fluids. In some embodiments, final hierarchical level 170 separates the coolant stream to correspond well to microchannels in the finned plate 200 and coalesces a plurality of individual fluid flows from the microchannels into a single liquid discharge.

In one or more of embodiments, HFD passages 172 and HFAL passages 174 may independently have a smallest dimension (e.g., width) in a range of about 0.1 millimeter (mm) to about 1 centimeter (cm) or about 0.3 mm to about 5 mm.

In one or more of embodiments, HFAV passages 173 may have a smallest dimension (e.g., width) in a range of about 0.01 mm to about 10 cm, or about 0.1 mm to about 1 cm.

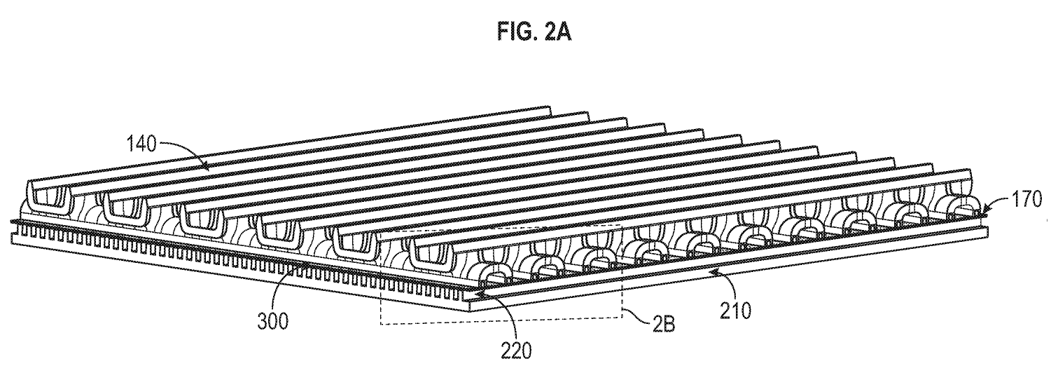

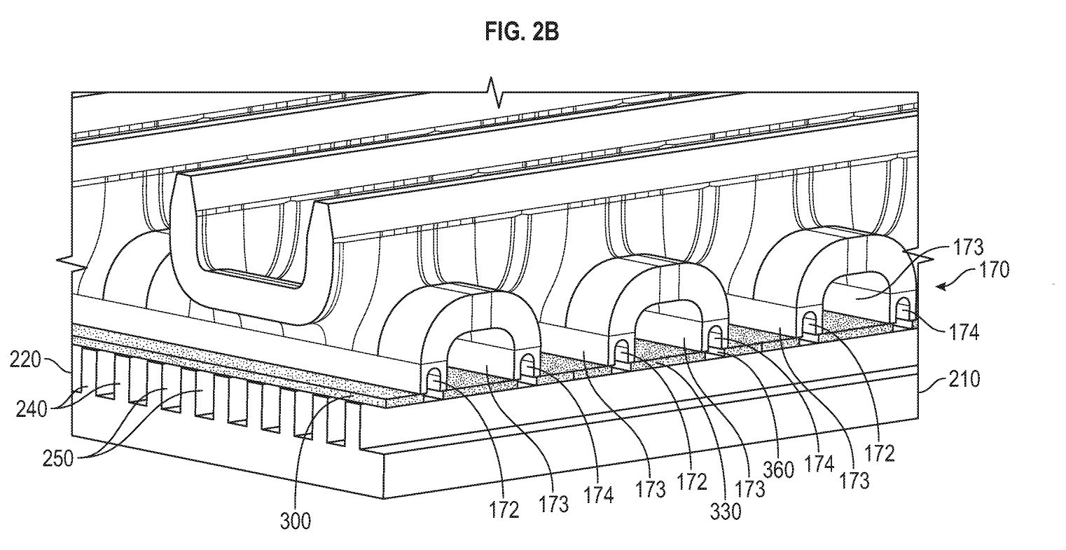

FIG. 2A shows an example base plate 210 and a microchannel array 220 on the base plate 210, which may be arranged on an electronic component to be cooled. First hierarchical level 140 is on final hierarchical level 170 and interface 300 is between microchannel array 220 and on final hierarchical level 170. Thermal energy in the electronic component is absorbed by the microchannel array 220 and transferred to a cool coolant stream as it enters the microchannel array 220 where the thermal energy generates the vapor discharge and warms the coolant stream to generate the liquid discharge. For example, the cool coolant stream may be vaporized, at least in part, and flow into the final hierarchical level 170 via the HFAV passages as the vapor discharge.

FIG. 2B is an expanded view of FIG. 2A showing a top boundary 260 of the microchannel array 220, a plurality of aligned microchannels 250, and a plurality of fins 240 in the microchannel array 220. The fins 240 are connected to and extend from a surface of the base plate 210, adjacent ones of the fins 240 being spaced apart from each other to form a plurality of microchannels 250 between the fins 240, one of the microchannels 250 being between each adjacent two of the fins 240. The microchannels 250 are in fluid communication with an interior of the two-phase manifold, e.g., passages in final hierarchical level 170. The microchannels 250 may extend in a direction parallel to each other and perpendicular to a direction of extension of passages in final hierarchical level 170, but the present disclosure is not limited thereto. FIG. 2B shows passages 172, 173, 174 of the final hierarchical level 170 extending perpendicular to the extension direction of the microchannels 250 and the inserts 330 and open areas 360 of the interface 300.

### Phase-Separating Interface

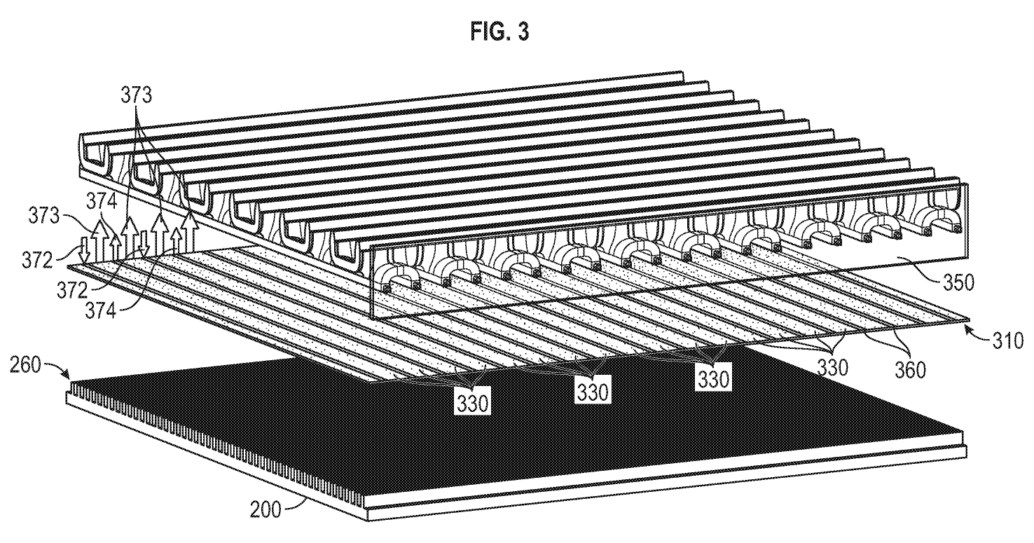

FIG. 3 shows interface 300 (e.g., phase-separating interface) with inserts 330 (e.g., screens, vapor vents, and/or gas permeable barriers) and open areas 360 that facilitate separation and/or removal of the vapor discharge from the liquid discharge (e.g., warm coolant stream). Coolant streams 372 flowing from HFD passages 172 are shown as downwardly pointing arrows. Vapor discharge streams 373 flowing into HFAV passages 173 and liquid discharge streams 374 flowing into HFAL passages 174 are shown as upwardly pointing arrows.

The inserts 330 may be implemented as (i) screens that are gas‑permeable and substantially liquid‑impermeable, and/or (ii) gas‑permeable barriers (e.g., porous membranes), either of which can be supported by a frame 350 integrated with the two- phase manifold. FIG. 3 shows frame 350 as transparent. The inserts 330 may include, or be coated with, a hydrophobic composition. In certain embodiments, the screens are positioned at entrances of the HFAV passages.

In an example embodiment, the phase-separating interface may be a unidirectional stack of alternating hydrophilic and hydrophobic layers. The unidirectional stack allows vapor flow from a channel into the vapor space and allows liquid flow from the vapor space back to the channel, e.g., in the event vapor condenses into liquid on the vapor side and begins to aggregate or pool. The vapor and liquid flows are “one-way flows” that do not occur in a reverse direction through the unidirectional stack. Without being limited by theory, the one-way vapor and liquid flows through the unidirectional stack may operate under the principles of a Janus membrane, for example, with dimensions designed according to the Eninger theory.

In one or more embodiments, the screens may be partially gas permeable and/or partially liquid impermeable. For example, the screens may be gas permeable in the direction from the microchannels into the two-phase manifold and gas impermeable in the direction from the two-phase manifold into the microchannels. The screens may be liquid permeable in the direction from the two-phase manifold into the microchannels and liquid impermeable in the direction from the microchannels into the two-phase manifold.

In one or more embodiments, the screens may allow small amounts of liquid phase vapor condensate to return to the microchannels and prevent or reduce pooling of the vapor condensate, which would otherwise remove the vapor condensate from the system.

In some embodiments, the open areas 360 may establish a capillary boundary that maintains a local pressure differential according to the Young–Laplace relation by selecting vent pore sizes sufficiently small to inhibit bulk liquid migration while permitting vapor egress. For example, the pore size may be selected by a surface contact angle. Without wishing to be limited by a particular theory, venting (e.g., egress) of the vapor through the pores may be determined or selected by at least one of a (i) height of the microchannel, (ii) a contact angle of a liquid facing side, (iii) a characteristic pore size (e.g., diameter for circular pores), or a (iv) thickness of the hydrophilic layer. For example, Eninger’s theory may be used to predict venting of the vapor through the pores if (e.g., when) the pore size is greater than or equal to about 1 um.

In one or more embodiments, the inserts 330 may be or include physical features to stop the ingress of liquid into the vapor passages and facilitate separation of the vapor and liquid streams, e.g., screens, mesh, baffles, semi-permeable layers, and/or the like.

In one or more embodiments, the inserts 330 may be screens that are gas permeable and substantially liquid impermeable. The screens are configured to separate the vapor discharge and the liquid discharge, and may include the first hydrophobic composition. For example, the surfaces of the screens may include a coating that includes the first hydrophobic composition.

In one or more embodiments the screens may include a porous mesh or membrane having a pore size (e.g., an average pore size) of at most about 100 micrometer (µm), for example, about 0.05 µm to about 100 µm, about 1 µm to about 50 µm, or about 2 µm to about 200 µm. The screens may be supported by a frame integrated with the bottom boundary of the two-phase manifold.

In one or more embodiments, the inserts 330 are gas permeable barriers and may be substantially liquid impermeable. The gas permeable barriers may include a second hydrophobic composition that prevents or reduces adhesion of the coolant stream to the gas permeable barriers and facilitates adhesion of the vapor discharge to the gas permeable barriers. In some embodiments the second hydrophobic composition is substantially the same as, or different than, the first hydrophobic composition, as described herein. In one or more embodiments, the gas permeable barriers may be gas-permeable layers, porous layers, and/or honeycomb-type layers.

In one or more embodiments, surfaces of the gas permeable barriers may include a coating, and the coating may include the second hydrophobic composition.

In one or more embodiments, the gas permeable barriers and/or the second hydrophobic composition may have pores sized to prevent liquid permeation and permit vapor permeation. The pores may have a pore size (e.g., an average pore size) of at most about 100 micrometer (µm), for example, about 0.05 µm to about 100 µm, about 1 µm to about 50 µm, or about 2 µm to about 200 µm.

FIG. 3 shows that the inserts 330 allow the vapor discharge 373 to flow between microchannel array 220 and final hierarchical level 170. The inserts 330 prevent liquid streams 372, 374 or other liquid from entering the HFAV vapor passages. Open areas 360 allow the liquid coolant 372 and 374 liquid discharge streams to flow, e.g., between the microchannel array 220 and the final hierarchical level 170. For example, the liquid discharge 374 (e.g., warm coolant stream) in the microchannel array 220 may flow upward into the HFAL passages 174.

In one or more embodiments, the open areas 360 may include screens, semi-permeable layers, gas permeable layers, microporous venting capillary pores, bidirectional or unidirectional liquid transport, and/or other physical features. The open areas 360 may be configured to provide or include a capillary boundary that provides a localized fluid pressure. The localized fluid pressure may be a capillary pressure related to a difference in pressure and/or surface tension across the microchannel array 220 and the HFAL passages 174. For example, the open areas 360 may have a vent pore size that is sufficiently small to provide the capillary boundary as provided by the Young-Laplace equation. In one or more embodiments, the vent pore size of the open areas 360, a width of microchannels 250, and a vent pore size of the HFAL passages 174 may independently be sufficiently small to provide the capillary boundary that may enhance or improve flow of the liquid discharge 374, e.g., from the microchannel array 220 into the HFAL passages 174.

FIG. 3 shows that the bottom boundary 310 and the top boundary 260 may each independently have a planar outer surface opposite to the interface 300. The planar outer surfaces and the interface 300 may be substantially flat or level and are configured to reduce or prevent loss and/or ingress of liquid and/or vapor from the two-phase manifold.

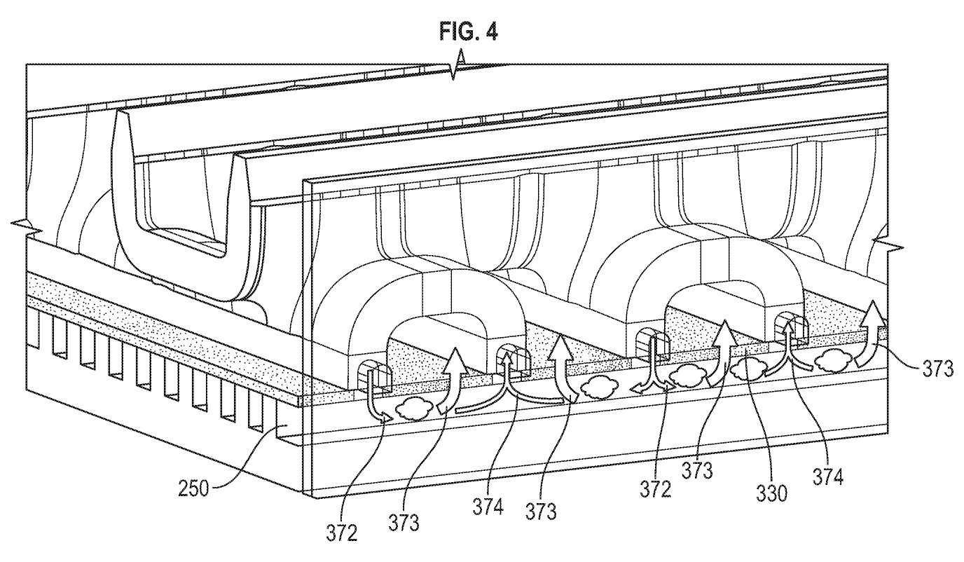

FIG. 4 is a more expanded view of FIG. 2A and shows coolant streams 372 entering the microchannel 250 where they absorb heat (e.g., from base plate 210 and fins 240) and at least a portion phase-changes into vapor discharge streams 373, as shown by a cloud in FIG. 4. Any un-vaporized portions flow out of the microchannel 250 as liquid discharge streams 374 into the final hierarchical level 170. FIG. 4 shows inserts 330 blocking liquid streams 372, 374 from entering the HFAV vapor passages, e.g., as the vapor discharges 373 flow out of the microchannel 250 into final hierarchical level 170.

In one or more embodiments, a width of the microchannels 250 (distance between two adjacent fins 240) may confine the coolant streams to a relatively short flow path before they reverse direction and exit the microchannel 250. The phrase “short flow path” as used herein, refers to the distance traveled by a coolant stream in a passage or microchannel. The reversal of flow within the microchannel 250, as illustrated in FIG. 4, may enhance heat absorption by the coolant stream and may minimize or reduce thermal resistance.

In one or more embodiments, the width of the microchannels 250 may be at most about 500 µm.

FIGS. 2A, 2B and 3 shows the microchannel array 220, fins 240, and microchannels 250 having a linear (e.g., straight) configuration with fins 240 being straight fins, but the present disclosure is not limited thereto.

In one or more embodiments, the fins may be straight fins pin fins, offset fins, louvered fins, and combinations thereof.

In one or more embodiments, the fins and microchannels may have a configuration that is non-linear, curved, divergent, and/or the like. For example, the finned plate may be a divergent finned plate having a divergent microchannel array including divergent fins and divergent microchannels.

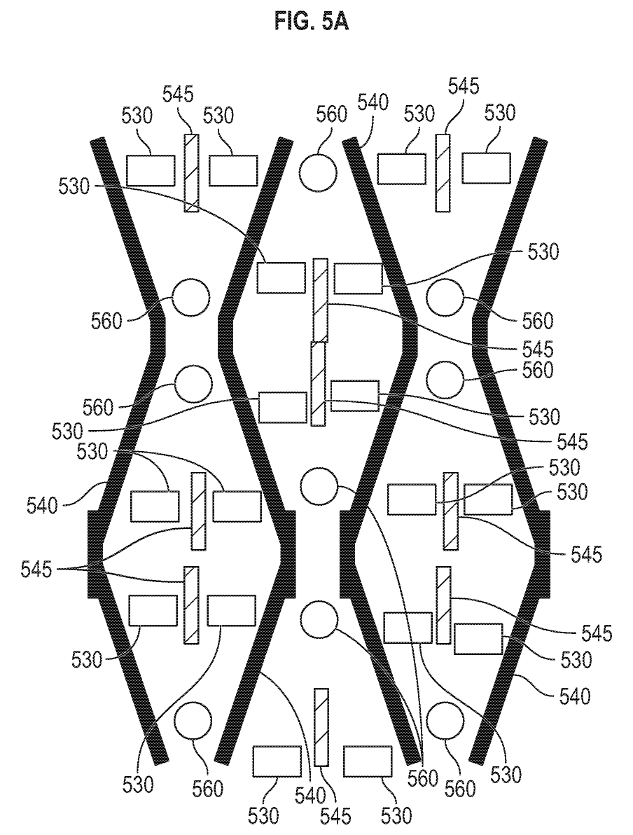

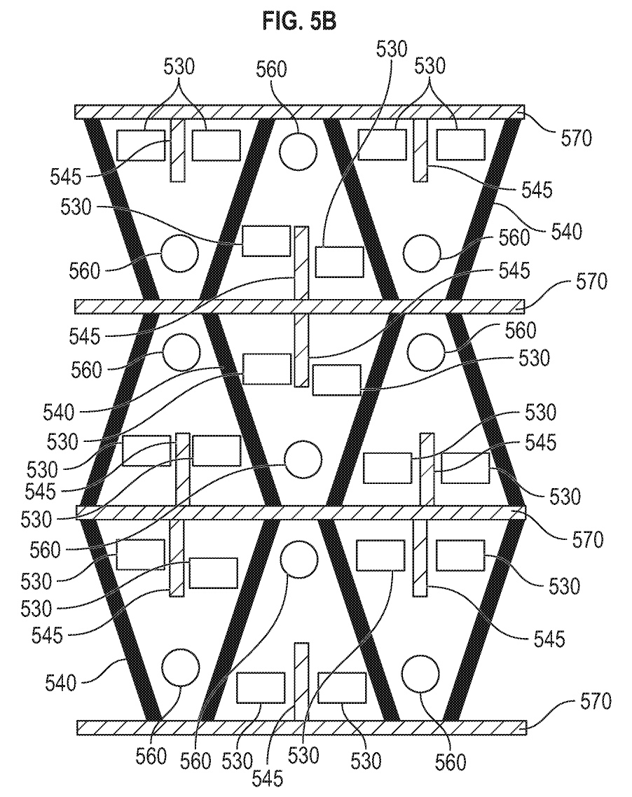

FIG. 5A is a plan view of a divergent microchannel array that includes divergent fins 540 that define divergent microchannels having primary flow directions extending in a direction parallel to each other. The divergent microchannels may have large regions 530 corresponding to (e.g., under) the inserts 330 and small regions 560 corresponding to (e.g., under) the open areas 360. The large regions 530 accommodate volume increases that occur as the coolant stream is vaporized in the divergent microchannel array and may minimize flow instabilities. For example, the divergent fins 540 and divergent microchannels may accommodate an increasing specific volume of a two-phase flow.

In one or more embodiments, the divergent microchannel array may include auxiliary fins 545, as shown in FIG. 5A. For example, the large regions 530 may include the auxiliary fins 545 that may provide flow channeling in the divergent microchannels.

FIG. 5B is a plan view of a divergent microchannel array that includes partition fins 570 that may be connected to and extend from a surface of the base plate 210. The partition fins 570 further reduce the short flow path of the coolant streams and may further enhance heat absorption by the coolant stream and further minimize or reduce thermal resistance. For example, the partition fins 570 may form or provide separated microchannels.

Surfaces of the fins according to one or more embodiments may include a coating. The coating may be selected to promote wetting by liquid coolant within the microchannel array. In one or more embodiments, surfaces of at least a portion of fins 240, divergent fins 540, auxiliary fins 545, and/or partition fins 570 may independently include at least one coating including a fluorinated composition, a third hydrophobic composition, a second hydrophilic composition, and any suitable combination thereof. For example, fins coated with the third hydrophobic composition and fins coated with the second hydrophilic composition may be arranged in an alternating pattern, or in alternating groups. In some embodiments, opposite sides of the fins are coated with the third hydrophobic composition and the second hydrophilic composition. The third hydrophobic composition may be substantially the same as, or different than, the first or second hydrophobic composition, as described herein. The second hydrophilic composition may be substantially the same as, or different than, the first hydrophilic composition, as described herein.

In some embodiments, a divergent two-phase manifold includes a divergent microchannel array and excludes (does not include) some or all of the ascending liquid passages. The manifold and microchannel array of the divergent two-phase manifold may be fabricated together as a single component to provide precise alignment between the manifold and microchannel. For example, the divergent two-phase manifold may be fabricated in an electrochemical additive manufacturing process.

### Additional Features of Two-Phase Manifold

The two-phase manifold may include auxiliary features in sections of passages between two hierarchical levels, non-limiting examples of which include flow dividing ribs, wings, an array of posts, an array of tubes, a truss structure, fins extending only from one side, and steps.

The two-phase manifold may include filtration selected from among mesh screens, porous materials, helical structures, vortex structures, and replaceable cartridges.

### Microchannels

In one or more of embodiments, a width of the microchannels may be about 1 micrometer (µm) to about 500 µm, about 5 µm to about 300 µm, or about 20 µm to about 120 µm. It is also understood that these ranges also include all sub-ranges and other ranges beginning and/or ending with any point within these ranges, for example, while the preceding range of about 20 µm to about 120 µm is disclosed, a range of, for example, about 40 µm to about 100 µm is also contemplated and included within the range. In one or more of embodiments, the finned plate may include about 50 to about 500 microchannels.

### Fins

In one or more of embodiments, the fins may include a thermally conductive material and may have a highest thermal conductivity axis with a conductivity of at least about 50 watt per meter degree K (W/m-K). In one or more of embodiments, the fins may include aluminum having a thermal conductivity of about 200 W/m-K, copper having a thermal conductivity of about 400 W/m-K, or a copper alloy having a thermal conductivity of about 350 Wm-K to about 400 W/m-K. In one or more of embodiments, the conductivity of the highest thermal conductivity axis of the fins may be about 400 W/m-K to about 3000 W/m-K, about 600 W/m-K to about 1500 W/m-K, or about 800 W/m-K to about 1200 W/m-K. It is also understood that these ranges also include all sub-ranges and other ranges beginning and/or ending with any point within these ranges, for example, while the preceding range of about 800 W/m-K to about 1200 W/m-K is disclosed, a range of, for example, about 900 W/m-K to about 1000 W/m-K is also contemplated and included within the range. The fins 240 may include a protective coating to reduce or prevent corrosion and the protective coating may include nickel, but the present disclosure is not limited thereto.

Aligned graphite has a thermal conductivity in a range of about 1000 W/m-K to about 1,500 W/m-K along its most thermally conductive axis (also referred to as its along-fin axis) compared with silicon, which has a thermal conductivity of about 100 W/m-K. Thus, aligned graphite enables higher fin efficiency (e.g., greater than about 50%) for high-aspect ratio fins (e.g., fins having a greater than 30:1 height to thickness ratio). In some embodiments, the fins may include aligned pyrolytic graphite having a thermal conductivity greater than 1000 W/m-K along the fin axis.

In one or more of embodiments, a thickness of the fins may be about 1 µm to about 500 µm, about 5 µm to about 300 µm, or about 20 µm to about 120 µm. It is also understood that these ranges also include all sub-ranges and other ranges beginning and/or ending with any point within these ranges, for example, while the preceding range of about 20 µm to about 120 µm is disclosed, a range of, for example, about 40 µm to about 100 µm is also contemplated and included within the range.

In one or more of embodiments, a height of the fins may be about 200 µm to about 5000 µm, about 400 µm to about 3,500 µm, or about 600 µm to about 1,800 µm. It is also understood that these ranges also include all sub-ranges and other ranges beginning and/or ending with any point within these ranges, for example, while the preceding range of about 600 µm to about 1,200 µm is disclosed, a range of, for example, about 900 µm to about 1000 µm is also contemplated and included within the range.

### Base Plate

The base plate has an optimum thickness to accommodate the stress caused when connecting the finned plate 200 to the two-phase manifold 100. If (e.g., when) the base plate is too thin, the stresses may cause the microchannel arrays to bow and/or curve, which may increase thermal interface resistance between the finned plate and a heat source (e.g., an electronic component). If (e.g., when) the base plate is too thick, the added (unnecessary) material may increase the thermal resistance of solid conduction.

The base plate may include thermal stress mitigating materials that have coefficient of thermal expansion (CTE) matching to the heat source material (e.g., a silicon electronic component) with relatively high compliance. For example, the CTE of CuMo and copper impregnated graphite (POCO) are each similar to silicon and POCO also has a relatively high shear compliance. Thermally induced stress due to CTE mismatch may be lower in POCO than in CuMo. Non-limiting examples of materials suitable for the base plate include CuW, Cu-diamond, Cu-SiC, and Cu-AlN.

The base plate may include at least one metal or metal-containing compound having high thermal conductivity. In some embodiments, the base plate 210 may include aluminum, carbon, copper, gold, molybdenum, nitrogen, palladium, platinum, silicon, silver, tungsten, graphite, diamond, an alloy thereof, a compound thereof, and a (e.g., any suitable) combination thereof. The base plate 210 may be manufactured using skiving, conventional machining (e.g., milling or sawing/cutting), or additive manufacturing (e.g., LBPF, SLS, ECAM, etc.), but the present disclosure is not limited thereto.

In one or more of embodiments, a thickness of the base plate may be about 10 µm to about 2000 µm, about 100 µm to about 1000 µm, or about 400 µm to about 600 µm. It is also understood that these ranges also include all sub-ranges and other ranges beginning and/or ending with any point within these ranges, for example, while the preceding range of about 250 µm to about 750 µm is disclosed, a range of, for example, about 300 µm to about 400 µm is also contemplated and included within the range.

In one or more of embodiments, a shear modulus of the base plate may be about 10 megapascal (MPa) to about 300 gigapascal (GPa), about 100 MPa to about 100 GPa, or about 1000 MPa to about 5 GPa. It is also understood that these ranges also include all sub-ranges and other ranges beginning and/or ending with any point within these ranges, for example, while the preceding range of about 100 MPa to about 100 GPa, is disclosed, a range of, for example, about 800 MPa to about 80 GPa is also contemplated and included within the range.

### Method of Making the Cooling Apparatus

According to one or more embodiments of the present disclosure, a method of making the cooling apparatus includes forming the two-phase manifold having the top, first hierarchical, and final hierarchical levels with descending passages, ascending vapor passages, and ascending liquid passages, and forming the finned plate having the microchannel array.

The method includes arranging the interface and the gas permeable barriers or the screens between the top boundary of the finned plate and entrances of the HFAV passages.

The method may include applying the first hydrophilic composition to the internal surfaces of the descending passages and the ascending liquid passages, and applying the first hydrophobic composition to the internal surfaces of the ascending vapor passages.

The method includes coupling the two-phase manifold to the finned plate across the interface.

In some embodiments, the fins and base plate may be manufactured using the same method or the fins may be fabricated onto a base plate that was previously fabricated using a different method (e.g., additive fins on a conventionally machined base plate). Additional machining may be performed on the finned plate after the fins are formed (e.g., holes drilled, edges cut to shape).

The methods may include a suitable additive manufacturing process (e.g., 3D printing), non-limiting examples of which include vat polymerization (e.g., stereolithography; digital light processing; scan, spin, and selectively photocure; continuous liquid interface production), powder bed fusion (e.g., selective laser sintering, direct metal laser sintering, selective laser melting, selective heat sintering, multi-jet fusion), binder jetting (e.g., 3DP, ExOne, VoxelJet, desktop metal), material jetting (e.g., Polyjet, Smooth Curvatures Printing, Multijet Modeling, Projet), sheet lamination (e.g., laminated object manufacture, selective deposition lamination, ultrasonic additive manufacturing), material extrusion (e.g., fused filament fabrication, fused deposition modeling, direct ink write), directed energy deposition (e.g., laser metal deposition, laser energy net shaping, direct metal depositions, laser engineered net shaping), hybrids of multiple additive manufacturing methods, and/or hybrids of additive and subtractive manufacturing methods. Subtractive manufacturing may refer to, as some examples, machining or computer numerical control (CNC) machining. In one or more embodiments, the manifold may be fabricated utilizing a hybrid process combining laser powder bed fusion (LPBF) for structural features and electrochemical additive manufacturing (ECAM) for fine-resolution internal channels. This hybrid approach enables high-density microchannel integration with minimal post-processing.

One or more suitable post-processing treatments may be used to remove unwanted material after additive manufacturing and provide for a better interior surface finish, e.g., electrochemical etching, flushing with fluid and abrasive media, vibration, or a combination thereof. The two-phase manifold and the finned plate may be fabricated in two or more parts and then bonded or gasketed together as described in more detail herein. The two-phase manifold and the finned plate may be manufactured as a single piece using additive manufacturing (e.g. LBPF, SLS, ECAM, etc.) methods to obtain single-piece construction.

According to one or more embodiments, the two-phase manifold, the finned plate, and the interface may be modular components and may be removably coupled or connected to each other.

Performance efficiency of the cooling apparatus may be improved by minimizing distances between inflow and outflow regions at an interface of the two-phase manifold and the finned plate. The two-phase manifold may have single walls that are non-thermally conductive or may have double walls including two solid layers coupled only at the top and/or bottom and nowhere in between to provide a continuous region of air separating the two layers. The single or double walls and the region of air are of minimum thickness as allowed by the additive material and its manufacturing process. These strategies ensure that the distance traveled by a coolant in a fluid passage (e.g., between exiting the manifold as cold inflow and reentering the manifold as hot outflow) is a short flow path and is minimized (reduced) to minimize (reduce) pressure drop and improve heat transfer. Minimizing wall and gap thicknesses provides short flow paths are as short as possible, which minimizes (reduces) frictional pressure loss and maximizes heat transfer due to maximization of developing regions.

The two-phase manifold may be or include a polymer, resin, metals, ceramics, glasses, composites, and/or a (e.g., any suitable) combination thereof. A low-thermal conductivity, high-temperature resin (e.g., with heat deflection temperature specification determined by application temperature boundary conditions) may be used in additive manufacture of the manifold to thermally isolate the cold inflow from the warm outflow (prevents preheating and preserves maximal temperature difference).

The double wall construction may be used in the two-phase manifold and may be manufactured from high thermal conductivity materials like metals, such that everywhere the cold inflow and hot outflow are oriented in adjacent cavities, the two are separated by a gap region with a gas state (e.g., air), for example cold inflow / metal manifold wall / air / metal manifold wall / hot outflow. Regions between the two walls may include air, an inert gas, a noble gas, aerogel, porous foam insulation, mechanical spacer features (e.g., periodic posts or spars), hollow microspheres (e.g. hollow glass microspheres), and/or a (e.g., any suitable) combination thereof. In some embodiments, the air gap (or gap region) may be filled with a low-conductivity gas such as xenon or krypton to further reduce thermal bridging. Alternatively, the gap may be evacuated to create a vacuum-insulated barrier.

### Additional Features of Cooling Apparatus

According to one or more embodiments of the present disclosure, the cooling apparatus may include a compression gasket and each of the finned plate and the two-phase manifold may have a sealing groove. The dimensions of the sealing groove may be iteratively optimized to provide sufficient sealing while also minimizing gasket compression-induced stresses, e.g., on the fins and/or the finned plate. The compression gasket may be an o-ring gasket and the sealing groove may be a recessed groove suitable for use with the o-ring gasket but the present disclosure is not limited thereto.

The compression gasket (e.g., o-ring gasket) may be or include rubber, silicone, other elastomeric materials, and/or a (e.g., any suitable) combination thereof. In some embodiments, the compression gasket may be a flat gasket or may be a formed-in-place gasket.

The finned plate may be coupled to the two-phase manifold with a bond interface such as a brazed bond, a soldered bond, an adhesive (e.g., epoxy) bond, a fusion bond, and/or a (e.g., any suitable) combination thereof. In one or more embodiments, the finned plate and the two-phase manifold may be fabricated as a single component and include a compression gasket and/or bond interface.

The cooling apparatus may include an air gap between the finned plate and the two-phase manifold. Differences in thermal expansion characteristics of the two components may result in uneven expansion of the two components that results in lateral stress, bending, delamination, and/or the like. The air gap enables the finned plate and the two-phase manifold to expand independently, thereby reducing mechanical stress.

The air gap may be continuous or segmented, and may be formed by spacers, ridges, or molded features in the manifold or bracket. In some embodiments, the air gap may be filled with a compliant material such as silicone foam, elastomeric foam, or inert gas to provide vibration damping while still allowing thermal expansion.

The two-phase manifold may include flow dividers configured to partition an input flow into flow stream sections. The flow dividers may be oriented vertically and/or horizontally and may be spaced apart at a distance that is regular, area preserving, or flowrate preserving. The flow dividers may include the same material from which the two-phase manifold is manufactured and may be flat and/or fin-shaped.

In one or more embodiments, each of the flow stream sections may have a substantially equal flowrate.

The flow dividers may be configured to modulate a Reynolds number of the flow stream sections. In some embodiments, the flow stream sections have a laminar flow. In one or more embodiments, the flow dividers are shaped to induce secondary flow structures that enhance convective heat transfer while maintaining laminar flow conditions.

In some embodiments, a space between two adjacent of the flow dividers may be an integral of a Poiseuille distribution of the flow stream.

The two-phase manifold may include internal flow-shaping structures having shapes that streamline fluid flow, reduce vortex formation, promote laminar flow, and/or reduce turbulence. In some embodiments, the flow-shaping structures may be at least one selected from among airfoil-shaped vanes (e.g., airfoils or hydrofoils), flow dividing ribs, wing-shaped vanes, arrays of posts, arrays of tubes, truss structures, fins, curved fins, streamlined baffles and steps. In some embodiments, the flow-shaping structures may reduce pressure drop, improve flow uniformity, and/or enhance thermal performance.

In some embodiments, the flow-shaping structures may be positioned to align with the direction of fluid flow. For example, the flow-shaping structures may not be fixed in place and may rotate to align with the direction of fluid flow. In some embodiments, the flow-shaping structures may be additively manufactured as part of the manifold body.

### Method of Operating the Cooling Apparatus

According to one or more embodiments, a method of operating the cooling apparatus of the present disclosure includes providing the liquid inflow including a coolant to the inlet; flowing the coolant from the inlet to the HFD passages and into the finned plate; vaporizing a first coolant portion to provide the vapor discharge; flowing at least of a portion of the vapor discharge into the HFAV passages; maintaining a liquid fraction within the microchannel array during operation by removing vapor through the HFAV passages to reduce dry-out and flow instabilities; flowing a second coolant portion in the finned plate to provide the liquid discharge; and flowing the liquid discharge into the HFAL passages. According to one or more embodiments, a method of operating the cooling apparatus of the present disclosure includes introducing a liquid coolant to the inlet; directing the liquid coolant through the TD and H1D passages to the HFD passages and into the microchannel array; generating vapor in the microchannel array; passing vapor from the microchannel array into the HFAV passages through the screens and to the vapor outlet; passing liquid from the microchannel array into the HFAL passages and to the liquid outlet; and maintaining a liquid fraction within the microchannel array during operation by routing vapor through the HFAV passages to reduce dry-out and flow instabilities.

In one or more embodiments, an amount of the liquid inflow is substantially equal to a total of an amount of the first coolant portion and an amount of the second coolant portion.

In one or more embodiments, less than the entire quantity of the coolant is vaporized during any point in the method, thus some liquid coolant returns in the ascending liquid passages. In some embodiments, the liquid coolant in the ascending liquid passages includes a portion of vapor.

In one or more embodiments, the method includes lowering the pressure within the cooling apparatus to facilitate the phase change (e.g., evaporation) of the liquid coolant stream to the vapor discharge at reduced temperatures. For example, a partial vacuum may be applied to the internal space of the within the cooling apparatus to lower the vapor pressure (e.g., apparent boiling temperature) of the liquid coolant stream.

### Cooling Systems

One or more aspects of embodiments of the present disclosure are directed toward a cooling system including at least one cooling apparatus including a finned plate and a two-phase manifold as described herein, at least one pump configured to circulate a coolant, and at least one heat exchanger in fluid communication with the two-phase manifold of the cooling apparatus.

The cooling system may include an electronic component and a cooling apparatus as described herein on the electronic component. The electronic component may include a semiconductor chip and/or an integrated circuit but the present disclosure in not limited thereto.

The cooling system may include a condenser configured to convert vapor collected at the vapor outlet to liquid.

The cooling system may include a return loop for the vapor outlet to the liquid inlet, the return loop including a condenser and a pump

The cooling system may include at least one auxiliary pump configured to lower the vapor pressure, for example of the vapor discharge (e.g., warm vapor discharge).

One or more aspects of embodiments of the present disclosure are directed toward a systems-level integrated cooling system including a plurality of cooling apparatuses each as described herein, a shared coolant distributor configured to supply a coolant to each of the plurality of cooling apparatus, a controller configured to monitor and adjust coolant flow rates to each of the plurality of cooling apparatuses based on thermal load, and a heat exchanger in fluid communication with the shared coolant distributor.

In some embodiments, the coolant streams and/or liquid discharge in the cooling apparatus, finned plate, and/or two-phase manifold and/or between the cooling apparatus and the heat exchanger may have a laminar flow or a non-laminar flow.

One or more aspects of embodiments of the present disclosure are directed toward a data center including a plurality of electronic components, at least one cooling system according to present disclosure, where the plurality of cooling apparatuses are on the plurality of electronic components.

For example, in one or more embodiments, the disclosed cooling architecture is desired or enhanced for deployment in AI data centers and other high-density computing environments where thermal uniformity and scalability are critical. The hierarchical two-phase manifold described herein may be integrated with modular cooling blocks that may be arranged in arrays across multiple server boards or racks. This modular approach enables rapid replacement and maintenance while preserving continuous operation, and supports system-level orchestration of coolant distribution through shared manifolding and centralized control loops.

The present disclosure further contemplates integration strategies that leverage hierarchical manifolding to reduce or minimize pressure drop across large-scale coolant networks. For example, top-level passages may interface with facility-level coolant distributors, while final hierarchical levels couple directly to microchannel arrays on individual chips. This arrangement facilitates predictable flow partitioning and phase management across thousands of electronic components, thereby reducing thermal hotspots and improving overall energy efficiency. These features are, e.g., for coordinated operation of multiple cooling apparatuses within a unified cooling system.

Terms such as "substantially," "about,” and "~" are utilized as terms of approximation and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ± 30%, 20%, 10%, 5% of the stated value.

Numerical ranges disclosed herein include and are intended to disclose all subsumed sub-ranges of the same numerical precision. For example, a range of "1.0 to 10.0" includes all sub-ranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

While the present disclosure has been described in connection with certain example embodiments, it is to be understood that the present disclosure is not limited to the disclosed embodiments, but, on the contrary, is intended to cover various modifications and equivalent arrangements included within the spirit and scope of the claims, and equivalents thereof.

The annotations used in this specification and FIGS. 1, 2A, 2B, 3, 4, 5A and 5B are listed hereafter.10: cooling apparatus

100: two-phase manifold

102: inlet

103: vapor outlet

104: liquid outlet

110: top level

112: top descending (TD) passage

113: top ascending vapor (TAV) passage

114: top ascending liquid (TAL) passage

140: first hierarchical level

142: first hierarchical descending (H1D) passage

143: first hierarchical ascending vapor (H1AV) passage

144: first hierarchical ascending liquid (H1AL) passage

150: second hierarchical level

170: final hierarchical level

172: final hierarchical descending (HFD) passage

173: final hierarchical ascending vapor (HFAV) passage

174: final hierarchical ascending liquid (HFAL) passage

200: finned plate

210: base plate

220: microchannel array

240: fin

250: microchannel

260: top boundary

300: interface

310: bottom boundary

330: insert

350: frame

360: open area

372: coolant stream

373: vapor discharge stream

374: liquid discharge stream

530: large region

540: divergent fin

545: auxiliary fin

560: small region

570: partition fin

H1AL: first hierarchical ascending liquid

H1AV: first hierarchical ascending vapor

H1D: first hierarchical descending

H2AL: second hierarchical ascending liquid

H2AV: second hierarchical ascending vapor

H2D: second hierarchical descending

HFAL: final hierarchical ascending liquid

HFAV: final hierarchical ascending vapor

HFD: final hierarchical descending

TAL: top ascending liquid

TAV: top ascending vapor

TDL: top descending liquid

What is claimed is:

1. A cooling apparatus comprising a two-phase manifold, a finned plate, and an interface,
the two-phase manifold comprising:
a top level comprising:
top descending (TD) passages open to at least one inlet in the top level and configured for a liquid inflow;
top ascending vapor (TAV) passages open to at least one vapor outlet in the top level and configured for a vapor discharge; and
top ascending liquid (TAL) passages open to at least one liquid outlet configured for a liquid discharge, the at least one liquid outlet being in the top level, a first hierarchical level, or a final hierarchical level,
the first hierarchical level comprising first hierarchical descending (H1D) passages, first hierarchical ascending vapor (H1AV) passages, and first hierarchical ascending liquid (H1AL) passages,
the final hierarchical level comprising final hierarchical descending (HFD) passages, final hierarchical ascending vapor (HFAV) passages, final hierarchical ascending liquid (HFAL) passages, and a bottom boundary,
the finned plate comprising a base plate, a microchannel array, and a top boundary, the microchannel array configured to generate the vapor discharge,
the interface configured to separate the vapor discharge and the liquid discharge, the interface comprising:
open areas between the top boundary and the HFD passages and the HFAL passages; and
barriers between the top boundary and the HFAV passages, the barriers being gas permeable.

2. The cooling apparatus of claim 1, wherein the liquid discharge is substantially vapor-free or a liquid-vapor mixture.

3. The cooling apparatus of claim 1, wherein a size of the TAV passages is greater than a size of each of the TD passages and the TAL passages, a size of H1AV passages is greater than a size of each of the H1D passages and the H1AL passages, and a size of the HFAV passages is greater than a size of each of the HFD passages and the HFAL passages.

4. The cooling apparatus of claim 1, wherein the interface is between the bottom boundary and the top boundary, the bottom boundary and the top boundary each have a planar outer surface opposite to the interface, or a combination thereof.

5. The cooling apparatus of claim 1, wherein the barriers are substantially liquid impermeable and comprise a second hydrophobic composition.

6. The cooling apparatus of claim 5, wherein surfaces of the barriers comprise a coating, the coating comprising the second hydrophobic composition.

7. The cooling apparatus of claim 5, wherein the second hydrophobic composition comprises a polymeric composition comprising at least one hydrophobic moiety.

8. The cooling apparatus of claim 1, wherein the open areas comprise a capillary boundary.

9. The cooling apparatus of claim 1, wherein
each of the H1D passages is open to the at least one inlet via the TD passages, each of the H1AV passages is open to the at least one vapor outlet via the TAV passages, each of the H1AL passages is open to the at least one liquid outlet and the TAL passages,
the two-phase manifold further comprises a second hierarchical level comprising second hierarchical descending (H2D) passages open to the H1D passages, second hierarchical ascending vapor (H2AV) passages open to the H1AV passages, and second hierarchical ascending liquid (H2AL) passages open to the H1AL passages, and
wherein the H2D passages are greater in number than the H1D passages, the H2AV passages are greater in number than the H1AV passages, and the H2AL passages are greater in number than the H1AL passages.

10. The cooling apparatus of claim 9, wherein
the at least one liquid outlet is in the second hierarchical level,
the TD passages, the TAV passages, and the TAL passages extend in an initial direction,
the H1D passages, the H1AV passages, and the H1AL passages extend in a first direction, the first direction substantially perpendicular to and crossing the initial direction, and
the H2D passages, the H2AV passages, and the H2AL passages extend in a second direction, the second direction substantially equivalent to the first direction.

11. The cooling apparatus of claim 1, wherein the microchannel array comprises fins and microchannels, the fins being connected to and extending from a surface of the base plate, each one of the microchannels being between each adjacent two of the fins, and an interior of the two-phase manifold is open to (in fluid communication with) the microchannels.

12. The cooling apparatus of claim 10, wherein microchannels in the microchannel array extend in a direction parallel to each other and perpendicular to a direction of extension of the HFD passages, and the microchannel array comprises
linear fins and linear microchannels, or
divergent fins and divergent microchannels, the divergent microchannels having large regions under the barriers and small regions under the open areas.

13. The cooling apparatus of claim 12, wherein the divergent fins comprise auxiliary fins in the large regions, and
the divergent microchannels are separated microchannels and the divergent fins comprise partition fins, or
the divergent microchannels are connected microchannels.

14. The cooling apparatus of claim 11, wherein surfaces of at least a portion of the fins comprises at least one coating, the coating comprising a fluorinated composition, a third hydrophobic composition, a second hydrophilic composition, or combination thereof.

15. The cooling apparatus of claim 11, wherein
the fins comprise a thermally conductive material and have a highest thermal conductivity axis with a conductivity of at least about 400 watt per meter degree K (W/m-K),
a thickness of the fins is about 1 micrometer (µm) to about 500 µm,
a height of the fins is about 200 µm to about 5000 µm,
the base plate comprises aluminum, carbon, copper, gold, molybdenum, nitrogen, palladium, platinum, silicon, silver, tungsten, graphite, diamond, an alloy thereof, a compound thereof, and any suitable combination thereof,
a thickness of the base plate is about 10 µm to about 2000 µm, and
a shear modulus of the base plate is about 10 megapascal (MPa) to about 300 gigapascal (GPa).

16. The cooling apparatus of claim 1, wherein the two-phase manifold, the finned plate, and the interface are modular and removably coupled.

17. A method of operating the cooling apparatus of claim 1, the method comprising:
providing the liquid inflow comprising a coolant to the at least one inlet;
flowing the coolant from the at least one inlet to the HFD passages and into the finned plate;
vaporizing a first coolant portion to provide the vapor discharge;
flowing at least of a portion of the vapor discharge into the HFAV passages;
maintaining a liquid fraction within the microchannel array during operation by removing vapor through the HFAV passages to reduce dry-out and flow instabilities;
flowing a second coolant portion in the finned plate to provide the liquid discharge; and
flowing the liquid discharge into the HFAL passages,
wherein an amount of the liquid inflow is substantially equal to a total of an amount of the first coolant portion and an amount of the second coolant portion.

18. A method of making the cooling apparatus of claim 1, the method comprising:
forming the two-phase manifold having the top, first hierarchical, and final hierarchical levels with descending passages, ascending vapor passages, and ascending liquid passages;
forming the finned plate having the microchannel array;arranging the interface and the barriers between the top boundary of the finned plate and entrances of the HFAV passages; and coupling the two-phase manifold to the finned plate across the interface.

19. A cooling system comprising:
at least one cooling apparatus comprising the cooling apparatus according to claim 1;
at least one pump configured to circulate a coolant;
at least one heat exchanger in fluid communication with the two-phase manifold of the cooling apparatus;
an electronic component, the cooling apparatus on the electronic component; and
a heat exchanger in fluid communication with the two-phase manifold of the cooling apparatus.

20. A data center comprising:
a plurality of electronic components; and
at least one cooling system comprising the cooling system according to claim 19,
wherein the plurality of cooling apparatuses are on the plurality of electronic components.
